(19) United States
(12) Patent Application Publication
(10) Pub. No.: US 2004/0130413 A1
(43) Pub. Date: Jul. 8, 2004

(54) Power supply system and method using analog coupling circuitry for power-line communications

(75) Inventors: James Mentz, Gainesville, FL (US); Bruce A. Denton, Ocala, FL (US); Gregory Allen Magin, Ocala, FL (US); Hassan Kaywan Afkhamie, Ocala, FL (US)

Correspondence Address: Allen, Dyer, Doppelt, Milbrath & Gilchrist, P.A., Suite 1401, 255 South Orange Avenue, P.O. Box 3791, Orlando, FL, 32802-3791, US

(73) Assignee: Intellon Corporation

(21) Appl. No.: 10/669,133

(22) Filed: Sep. 23, 2003

Related U.S. Application Data
(60) Provisional application No. 60/413,292, filed on Sep. 25, 2002.

(51) Int. Cl. H03H 7/00

(52) U.S. Cl. 333/167; 340/310.01

(57) ABSTRACT

Coupling circuitry implemented with passive components is added to a conventional power supply to enable communications access to a power-line network by a device designed for power-line communications (“PLC device”), in order to achieve certain benefits including minimizing costs.

Conventional PLC devices access the power-line network via coupling circuitry built into the PLC device and a separate cable that connects the PLC device to a power outlet. With this invention the PLC device may use the coupling circuitry that is built into a host's existing power supply, thus providing at least two distinct advantages: 1) only one cable is necessary to connect the host device to the power-line network, and 2) the design of the PLC device is simplified since it is not connected to high-voltage line.

### PRIORITY

This application claims priority from Provisional Application, Serial. No. 60,413,292, filed Sep. 25, 2003.

### BACKGROUND OF THE INVENTION

1. Field of the Invention

The present invention relates to power-line communications (PLC) networking in general and particularly to the design of a power supply with built-in analog coupling to allow simplified integration of PLC devices within a host device.

2. Description of Related Art

Techniques for home networking over residential power lines have received considerable attention in recent years. The HomePlug Powerline Alliance, for example, has established a high-speed networking standard, and to date several manufacturers are producing and marketing PLC devices for the consumer market that are interoperable under HomePlug standards.

A typical system 10 in which a consumer employs PLC devices 12, 14 is depicted in FIG. 1. Each of two hosts 16, 18 being networked are connected to the respective PLC devices 12, 14 that are in turn connected to residential power-line network 20. Each PLC device 12, 14 incorporates (i) a digital processor 22, (ii) an analog front end (AFE) 24, and (iii) power-line coupling circuitry 26 for receiving the power line 28. A connection 17, 19 between each host 16, 18 and the respective PLC device 12, 14 exists for communication purposes only; thus, if a host 16,18 also requires power from the residential power-network 20 (for example, if a host is a Personal Computer, a Printer, a DSL or Cable Modem, etc.) there must exist a second connection 30 from the host 16, 18 to the power-line 28 for the purpose of providing electrical power to the host device. In the exemplary Power Line Network of FIG. 1, one Host 16 has an internal power supply 31, and the second Host 18 has an external power supply 33. The present invention applies to both types of power supplies.

### SUMMARY OF THE INVENTION

In accordance with this invention, an internal or external power supply of the type used as a power supply for an electronic device that is a host for a PLC device incorporates passive coupling circuitry necessary to interface the power line to the AFE section of a PLC device. A passive coupling circuitry (coupler) is used with any PLC devices in the system to connect the communication signal to the power line. The coupler is designed to pass any high-frequency communication signals and rejects the line 60 Hz (50 Hz) power. The coupler also provides a first level of transient protection to the PLC device. By including the coupling circuitry in the host's power supply, a PLC device is simplified to now contain the digital processing and an AFE. For example, as shown in FIG. 2, after the incorporation of the present invention in the scenario of FIG. 1, two host devices 12, 14 can be connected to the residential power line 20 via a single path 32 through a coupler 34 according to this invention, as opposed to the two power-line connections 28, 30 required in the scenario of FIG. 1.

### DESCRIPTION OF THE DRAWING

A better understanding of the present invention can be obtained when the following detailed description of a preferred embodiment is considered in conjunction with the drawings, in which:

FIG. 1 is a block diagram of a prior art PLC system.

FIG. 2 is a simplified block diagram illustrating a PLC system according to the present invention.

FIG. 3 is a block diagram of an exemplary host system (for example, a personal computer, printer, DSL or Cable Modem) employing the invention, i.e., an internal power supply that incorporates the power-line communications signal coupling and a PLC device that connects to the power-line via the power supply.

FIG. 4 is a diagram of a preferred embodiment of a power supply that includes the passive power-line coupling circuitry in accordance with the invention.

FIG. 5 is a functional diagram of circuitry for combining/separating the power-line communications signal and the DC power signal.

FIG. 6 is a diagram of an exemplary host system (for example, a notebook computer, printer, DSL or Cable Modem) employing the invention, i.e., an external power supply that incorporates the power-line communications signal coupling and a PLC device that connects to the power-line via the power supply. The exemplary system also utilizes circuitry for combining and separating a DC power signal and a power-line communications signal.

FIG. 7 is a diagram of a preferred embodiment of a power supply that includes the power-line coupling circuitry, as well as circuitry to combine/separate the power signal and communications signal.

FIG. 8 is a diagram of a preferred embodiment of a circuitry for combining/separating the power signal and communications signal in the host device.

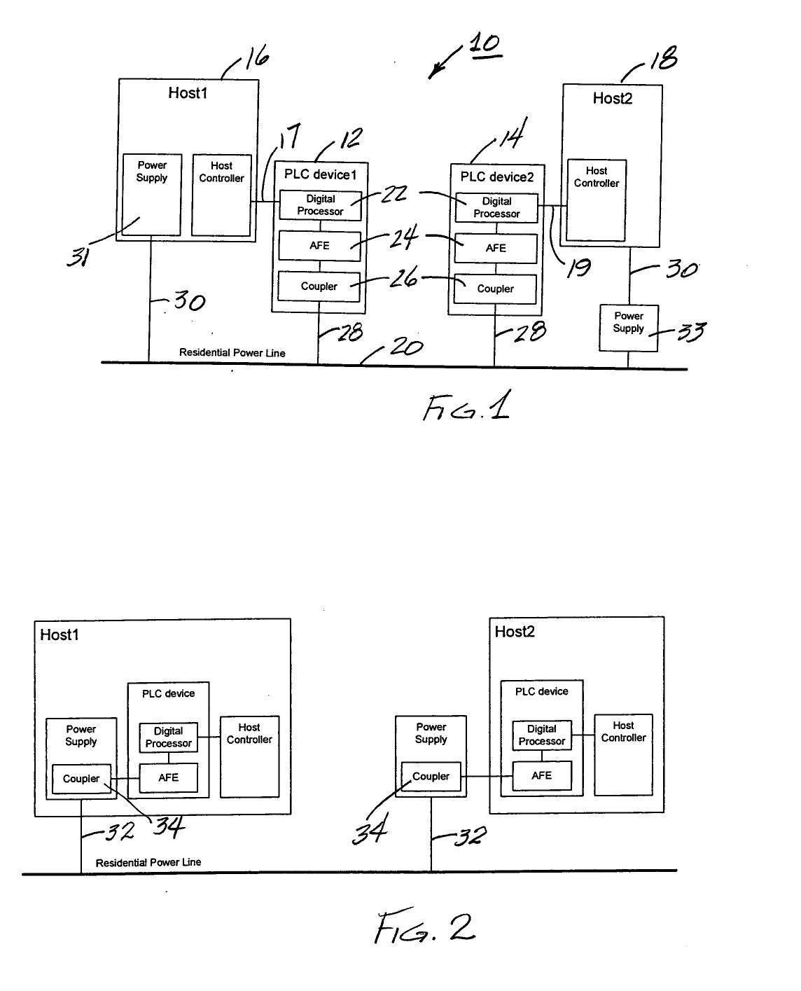

### DETAILED DESCRIPTION

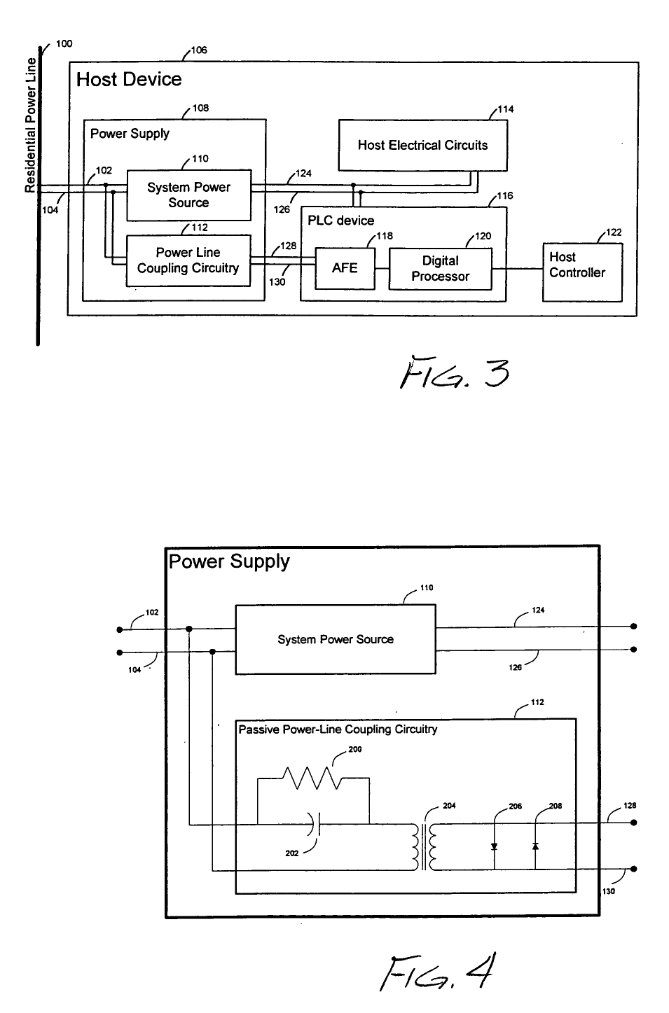

Referring to FIG. 3, a host system 106 incorporates a power supply 108 that connects to the residential power line 100 through a line terminal 102 and a neutral terminal 104. The power supply 108 is constructed in accordance with the present invention and thus contains power-line coupling circuitry 112 in addition to the conventional system power source 110. The system power source typically delivers DC power to the host electrical circuitry 114 as well as the PLC device 116. The power delivery should be unaffected by the addition of the power-line coupling circuitry 112 to the power supply 108. The PLC device 116 consists of an AFE 118 and a Digital Processor 120. The AFE 118 interfaces to the coupling circuitry that is now part of the host power supply 108, and performs the D/A (digital-to-analog) and A/D (analog-to-digital) conversion as well as to implement various transmit or receive filtering functions and gain stages on the analog side. The digital processor 120 contained in the PLC device, also performs both transmit and receive functions, and interfaces to a host controller 122 which either provides it data for transmission or accepts received data from the PLC device's digital processor 120. The digital data may, for example, represent Internet data, streaming audio or video.

An additional benefit of the invention is that with the removal of coupling circuitry from the PLC device, no UL certification of the PLC device is required. It is the power supply that is burdened with UL certification, however a power supply must comply with UL specifications in any case, and the addition of the coupling circuitry should not represent an issue in this respect.

A preferred embodiment of the passive power-line coupling circuitry is shown in FIG. 4. The power-line coupling circuitry shares on one side the line and neutral wires (102 and 104 in FIG. 3) that connect to the residential power line, but provides a second set of connections (128 and 130 in FIG. 3) to serve as an interface from the power supply to the PLC device.

Referring to FIG. 4, the schematic of the passive power-line coupling circuitry is shown.

The line and neutral wires 102 and 104 connect to the residential power line. The capacitor 202 and the primary of transformer 204 form a high pass filter, allowing the power-line communications signal to pass and rejecting the line frequency (50 or 60 Hz). The two diodes 206 and 208 provide transient protection to the PLC device.

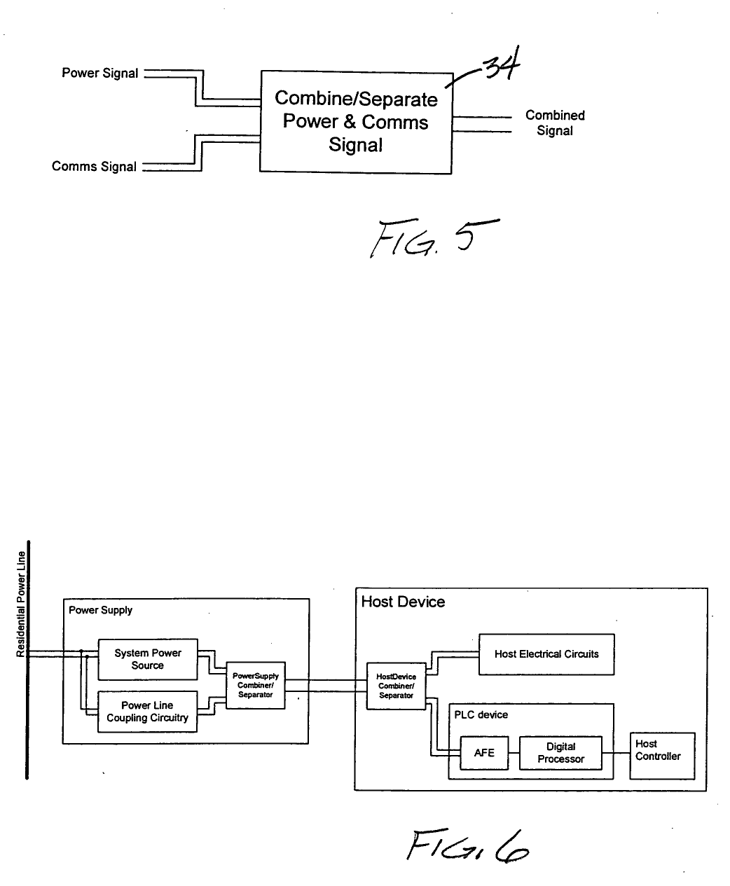

The power supply of FIG. 4 provides separate connections for the DC power signal across lines 124 and 126, and for the communication signal across lines 128 and 130. In some instances it may be advantageous to combine the two signals inside the power supply and provide a single connection. This may, for example, be the case if the power supply is to be deployed external to the host device, but only one signal cable is provided between the external power supply and the host device. Additional circuitry is then required to combine the power and communication signals in the power supply and potentially to separate the power signal and the communication signal on the side of the PLC device. Such circuitry is readily derived, but may vary considerably according to the requirements of the particular power supply or host device. Conceptually, such circuitry is described by the embodiment illustrated in FIG. 5.

A circuit as depicted schematically in FIG. 5 may be incorporated both in the power supply and in the host device to combine and separate the DC power signal and the power line communications signal. FIG. 6 is a diagram of a preferred embodiment of the invention including the Combiner/Separator circuitry, with a host device that utilizes an external power supply.

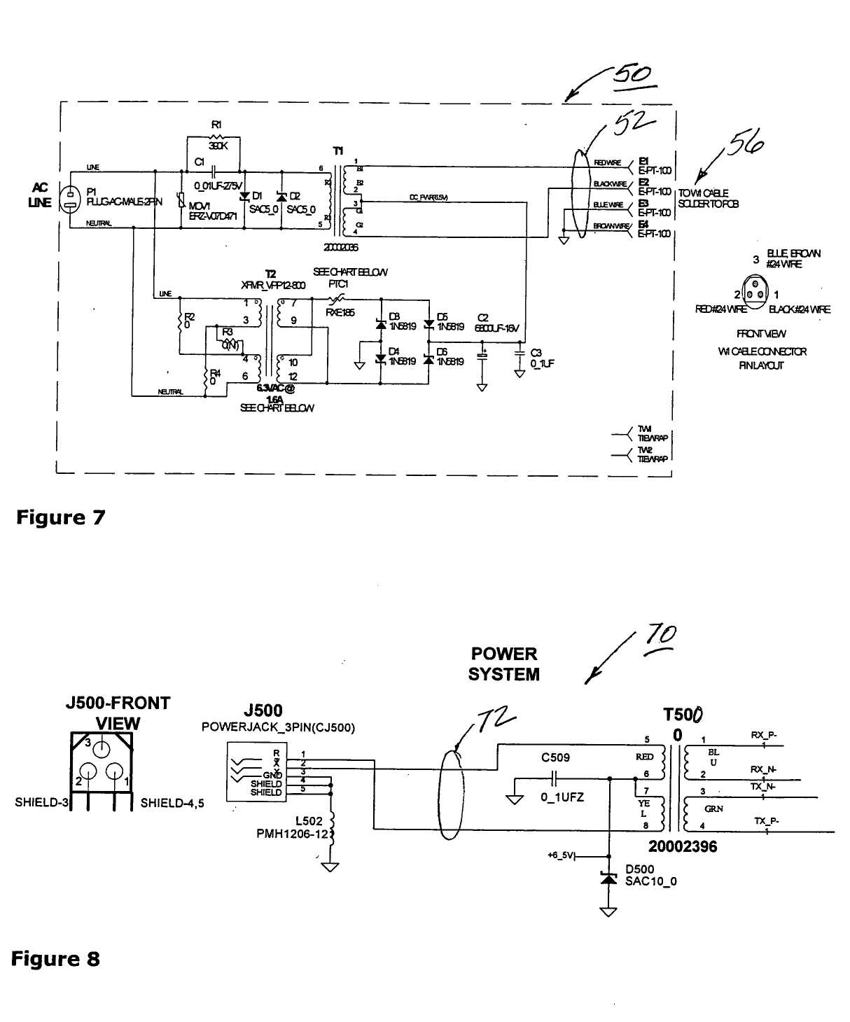

A preferred embodiment of an external power supply with circuitry 50 for combining/separating the power signal and communications signal is depicted in FIG. 7. FIG. 8 depicts a preferred embodiment of circuitry 70 that can be integrated in a host device as shown by example in FIG. 6. The circuitry 50 depicted in FIG. 7 contains two diferent transformers T1 and T2. T2 is used as part of a low voltage power supply. This is an unregulated linear power supply with a DC output, but the concept applies equally to any switched power supply that has a low voltage output. Signal coupling transfer T1 couples the signal from a power-line to the power supply cable 56. The signal being transferred across T1 can be treated as a differential signal that is centered on a neutral value. The neutral value used is the low voltage output of the power supply, which is injected onto the secondary (right hand) side of the transformer with a center tap. The secondary side of transformer T1 contains both an AC signal and the low voltage current necessary to operate a host device, such as depicted in FIG. 2 and described with reference thereto.

A three wire cable 52 connects the power supply of FIG. 7 to corresponding circuitry incorporated in the host device. One wire is ground. The other two wires are redundant carriers of the low voltage DC power signal, and carriers of the differential power-line communications signal.

In the preferred embodiment of the host device circuitry 70 of FIG. 8, a transformer T500 couples the differential communication signals off of the signal wire pair 72 from Powerjack J500. This pair 72 can also be center tapped to extract a low-voltage DC current without shorting the differential communication signals.

The design in the preferred embodiments of FIG. 7 and FIG. 8 has several advantages over other power-line signal coupling methods. The communication signals are injected onto a redundant set of low voltage DC wires instead of between a low voltage wire and ground, which saves the necessity for high quality inductors to isolate the communication signals from the low impedance between power and ground connection in the low-voltage power supply. Such high quality inductors are expensive and not readily available in large quantities. When such inductors have been improperly substituted with lesser quality parts, the communications performance of a prior art device has been reduced.

The embodiment of FIGS. 7 and 8 also minimizes the cost added to a conventional power supply. The same power supplies can be used with several products. Compared with a host device that utilizes an internal power supply, the embodiment represented with FIGS. 7 and 8 has the advantage of removing the power supply's space and heat dissipation requirements from inside the host device.

What is claimed is:

1. A power-line communication system, comprising:
a communication device for receiving and transmitting communication signals;
a power supply connected between a power-line and the communication device for supplying power to the communication device; and
coupling means with the power supply for facilitating transmission of both line power and the communication signals to the communication device through the power supply.

2. The system recited in claim 1 wherein the coupling means facilitates transmission of both line power and the communication signals along a single connection.

3. The system recited in claim 2 wherein the coupling means comprises a high pass filter for transmitting the communication signals and rejecting power-line frequencies.

4. The system recited in claim 3 further comprising means providing transient protection for the communication device.

5. The system recited in claim 1 further comprising means for injecting the communication signals onto a ground-free, low voltage direct-current path.

6. The system recited in claim 5 further comprising a redundant ground-free low voltage direct-current path.

7. The system recited in claim 1 wherein the power supply comprises a transformer having a center tap to extract a low-voltage direct-current component without shorting the communication signals.
